(19) United States
(12) Patent Application Publication
(10) Pub. No.: US 2025/0048528 A1
(43) Pub. Date: Feb. 6, 2025

(54) PLASMA TORCH AND PLASMA SCRUBBER APPARATUS INCLUDING THE SAME

(71) Applicant: Samsung Electronics Co., Ltd., Suwon-si (KR)

(72) Inventors: Hyunwoo Park, Suwon-si (KR); Jae-Hyun Kim, Suwon-si (KR); Hyunsik Kim, Suwon-si (KR); Taijong Sung, Suwon-si (KR); Young Heo, Suwon-si (KR)

(73) Assignee: Samsung Electronics Co., Ltd., Suwon-si (KR)

(21) Appl. No.: 18/427,431

(22) Filed: Jan. 30, 2024

(30) Foreign Application Priority Data
Aug. 2, 2023 (KR) 10-2023-0101034

(51) Int. Cl. H05H 1/34

(52) U.S. Cl. CPC H05H 1/3494

(57) ABSTRACT

A plasma torch includes a cathode, a pilot electrode disposed on a first outer circumference of the cathode and separated from an exterior surface of the cathode, an electrode protection member disposed below the pilot electrode and including a first insulator, an anode disposed on a second outer circumference of a process space and disposed below the pilot electrode, and a discharge gas flow path coupled to a separation gap formed between the exterior surface of the cathode and an inner surface of the pilot electrode. The discharge gas flow path is configured to supply a discharge gas.

### CROSS-REFERENCE TO RELATED APPLICATIONS

This application claims benefit of priority under 35 U.S.C. § 119 to Korean Patent Application No. 10-2023-0101034, filed on Aug. 2, 2023, in the Korean Intellectual Property Office, the disclosure of which is incorporated by reference herein in its entirety.

### BACKGROUND

### 1. Field

The present disclosure relates generally to plasma scrubbers, and more particularly, to a plasma torch and a plasma scrubber apparatus including the same.

### 2. Description of Related Art

Related techniques for manufacturing semiconductor devices may use a substrate processing apparatus to perform steps such as, but not be limited to, deposition and/or etching. The substrate processing apparatus may include a process chamber. For example, the substrate processing apparatus may discharge various gases during the processing of the substrate. These gases may be discharged together with a material generated during the substrate processing. If the discharged materials are directly discharged to an external space (e.g., the outside), the discharged materials may present and/or cause environmental concerns. Thus, in order to reduce and/or prevent the discharging of the materials, the gases discharged from the substrate processing apparatus may be processed through a scrubber apparatus prior to being discharged to the external space (e.g., the outside). For example, the scrubber apparatus may include a plasma scrubber apparatus that may be configured to heat-treat the discharged gases by using plasma.

### SUMMARY

One or more example embodiments of the present disclosure provide a plasma torch and a plasma scrubber apparatus including the same for treating a waste gas generated during processing of a substrate by using plasma.

According to an aspect of the present disclosure, a plasma torch includes a cathode, a pilot electrode disposed on a first outer circumference of the cathode and separated from an exterior surface of the cathode, an electrode protection member disposed below the pilot electrode and including a first insulator, an anode disposed on a second outer circumference of a process space and disposed below the pilot electrode, and a discharge gas flow path coupled to a separation gap formed between the exterior surface of the cathode and an inner surface of the pilot electrode. The discharge gas flow path is configured to supply a discharge gas.

According to an aspect of the present disclosure, a plasma torch includes a cathode, a pilot electrode disposed on a first outer circumference of the cathode and separated from an exterior surface of the cathode, an anode disposed on a second outer circumference of a process space and disposed below the pilot electrode, a discharge gas flow path coupled to a separation gap formed between the exterior surface of the cathode and an inner surface of the pilot electrode, an electrode protection member disposed below the pilot electrode and includes a first insulator, an upper blocking member including a second insulator, disposed on an upper area of the anode, and at least partially surrounding the process space, and a lower blocking member including a third insulator, disposed on a lower area of the anode, and at least partially surrounding the process space. The discharge gas flow path is configured to supply a discharge gas.

According to an aspect of the present disclosure, a plasma torch includes a cathode, a pilot electrode disposed on a first outer circumference of the cathode and separated from an exterior surface of the cathode, an electrode protection member disposed below the pilot electrode and includes a first insulator, an anode disposed on a second outer circumference of a process space and disposed below the pilot electrode, a discharge gas flow path coupled to a separation gap formed between the exterior surface of the cathode and an inner surface of the pilot electrode, the discharge gas flow path being configured to supply a discharge gas, an upper reaction gas flow path configured to supply a reaction gas to an area adjacent to a discharge port, and a lower reaction gas flow path configured to supply the reaction gas to an area positioned below the anode. The discharge port is formed inside a lower end portion of the pilot electrode. The reaction gas has a reactivity with by-products generated after a waste gas is thermally decomposed by plasma.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a view showing a plasma torch, according to an embodiment;

FIG. 2 is a view showing an upper part of a plasma torch in FIG. 1, according to an embodiment;

FIG. 3 is a transverse cross-sectional view of a lower part of a pilot electrode, according to an embodiment;

FIG. 4 is a transverse cross-sectional view of a point in an up-down direction at an anode, according to an embodiment;

FIG. 5 is a view showing a plasma torch in an operation state, according to an embodiment;

FIG. 6 is a transverse cross-sectional view of a region where a waste gas inflow portion and an inflow path are positioned, according to an embodiment;

FIG. 7 is a block diagram showing a control relationship of a plasma torch, according to an embodiment;

FIG. 8 is a block diagram showing a control relationship of a plasma torch, according to another embodiment;

FIG. 9 is a view showing a plasma scrubber apparatus including a plasma torch, according to an embodiment; and

FIG. 10 is a view showing a semiconductor production equipment including a plasma scrubber apparatus of FIG. 9, according to an embodiment.

### DETAILED DESCRIPTION

Hereinafter, embodiments of the present disclosure are described with reference to the accompanying drawings so that those with ordinary skill in the art to which the present disclosure pertains may carry out the embodiments. As those skilled in the art may understand, the described embodiments may be modified in various different ways without departing from the spirit and/or scope of the present disclosure.

In order to clarify the present disclosure, parts that are not connected with the description may be omitted, and the same elements and/or equivalents may be referred to by the same reference numerals throughout the specification.

Further, since sizes and thicknesses of constituent members shown in the accompanying drawings are arbitrarily given for better understanding and ease of description, the present disclosure may not be limited to the illustrated sizes and thicknesses. In the drawings, the thickness of layers, films, panels, regions, and the like, may be exaggerated for clarity. In the drawings, for better understanding and ease of description, thicknesses of some layers and areas may be excessively displayed.

It is to be understood that when an element such as a layer, film, region, and/or substrate is referred to as being “on” another element, the element may be directly on the other element and/or intervening elements may also be present. In contrast, when an element is referred to as being “directly on” another element, there may be no intervening elements present. Further, as used herein, the terms “on” and/or “above” may refer to being positioned on or below the object portion, and may not necessarily refer to being positioned on the upper side of the object portion based on a gravitational direction.

In addition, unless explicitly described to the contrary, the term “comprise”, and variations such as “comprises” and/or “comprising”, are to be understood to imply the inclusion of stated elements but not the exclusion of any other elements.

As used herein, the phrase “on a plane” may refer to an object portion being viewed from above, and the phrase “on a cross-section” may refer to viewing, from the side, a cross-section taken by vertically cutting an object portion.

It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order).

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

As used herein, each of the terms “Cl₂”, “F₂”, “HCl”, “NH₃”, and the like may refer to a material made of elements included in each of the terms and is not a chemical formula representing a stoichiometric relationship.

Hereinafter, various embodiments of the present disclosure are described with reference to the accompanying drawings.

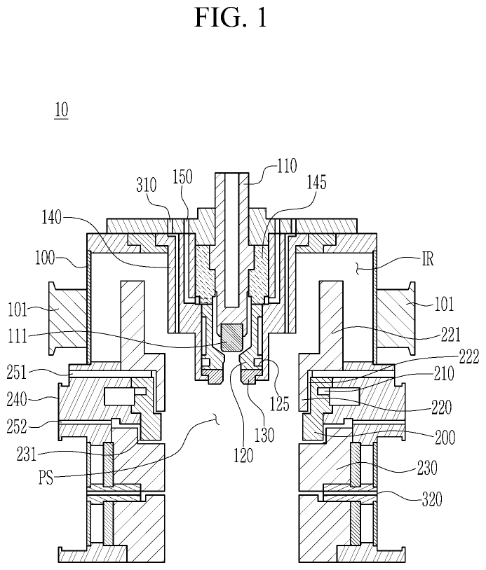

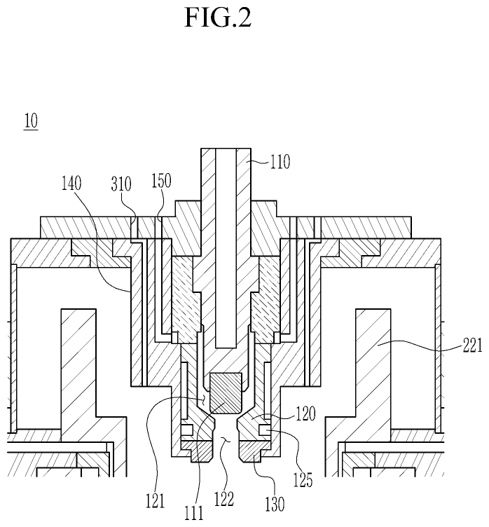

FIG. 1 is a view showing a plasma torch, according to an embodiment. FIG. 2 is a view representing an upper part of a plasma torch in FIG. 1, according to an embodiment.

Referring to FIG. 1 and FIG. 2, a plasma torch 10, according to an embodiment, may include a housing 100, a cathode 111, a pilot electrode 120, and an anode 200.

The housing 100 may form a space in which a waste gas, which may be a decomposition target, may be accommodated. A waste gas inflow portion 101 may be disposed on one side of the housing 100. The length direction of the waste gas inflow portion 101 may be provided eccentrically in a radial direction with respect to the straight line passing through the inner central region of the housing 100. At least one waste gas inflow portion 101 may be provided along the circumference direction of the housing 100 with the up-down direction as an axis. The waste gas inflow portion 101 may allow the waste gas to inflow into the housing 100. An inflow path IR may be disposed inside the housing 100, such that the waste gas from the waste gas inflow portion 101 may flow into the housing 100. The inflow path IR may be disposed at a height corresponding to the waste gas inflow portion 101.

The cathode 111 may be disposed on the inner space of the housing 100. The cathode 111 may consist of and/or include a conductive material. For example, the cathode 111 may be made of and/or include tungsten (W), thorium (Th), and/or a combination thereof. The cathode 111 may be connected (e.g., coupled) to a lower portion of a cathode supporting member 110. The cathode supporting member 110 may be provided in a pillar structure. The cathode supporting member 110 may be connected to the housing 100. The cathode supporting member 110 may consist of and/or include a conductive material. That is, when a voltage is applied to the cathode supporting member 110, the same and/or a substantially similar voltage may be applied to the cathode 111 through the cathode supporting member 110. The upper end portion of the cathode supporting member 110 may be exposed to an external space (e.g., the outside).

The pilot electrode 120 may be disposed on an outer circumference of the cathode 111. The pilot electrode 120 may be provided as a piping structure. The outer region of the pilot electrode 120 may be disposed to be spaced apart from the inner surface of the housing 100. The pilot electrode 120 may consist of and/or include a conductive material. For example, the pilot electrode 120 may be made of and/or include a conductive material such as, but not limited to, copper (Cu) and the like. The inner side of the pilot electrode 120 may be disposed to be spaced apart from the exterior surface of the cathode 111. The upper end portion of the pilot electrode 120 may be disposed above the upper end portion of the cathode 111. The lower end portion of the pilot electrode 120 may be disposed lower than the lower end portion of the cathode 111. The inner surface of the lower portion of the pilot electrode 120 may be inclined toward the inner center in at least one region.

A separation gap 121 may be formed between the inner surface of the pilot electrode 120 and the exterior surface of the cathode 111. A discharge port 122 may be formed inside the lower end of the pilot electrode 120. The separation gap 121 may be connected to the discharge port 122. The discharge port 122 may be disposed below the cathode 111. For example, the discharge port 122 may be disposed at a side that may be lower than the waste gas inflow portion 101.

The pilot electrode 120 may be connected to the electrode supporting member 140. The electrode supporting member 140 may be disposed on the outer circumference of the pilot electrode 120. The electrode supporting member 140 may be connected to the housing 100. The exterior surface of the electrode supporting member 140 may be disposed to be spaced from the inner surface of the housing 100. Accordingly, an inflow path IR may be formed between the exterior surface of the electrode supporting member 140 and the inner surface of the housing 100.

The pilot electrode 120 may be disposed in a space formed inside the electrode supporting member 140. The electrode supporting member 140 may consist of and/or may include a conductive material. That is, when a voltage is applied to the electrode supporting member 140, the same and/or a substantially similar voltage may be applied to the pilot electrode 120. The electrode supporting member 140 and the cathode supporting member 110 may be provided in a state insulated from each other. For example, an insulating member 145 may be disposed between a region where the electrode supporting member 140 and the cathode supporting member 110 face each other.

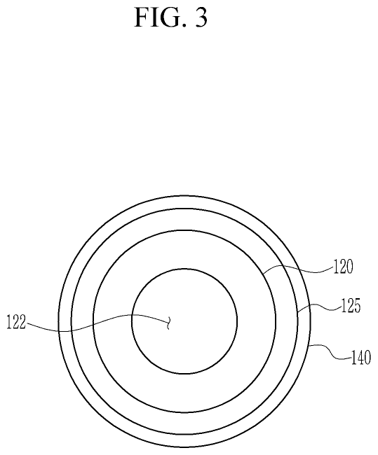

FIG. 3 is a transverse cross-sectional view of a lower portion of a pilot electrode, according to an embodiment.

Referring to FIG. 3, a pilot magnet 125 may be disposed on the outer circumference of the pilot electrode 120. The pilot magnet 125 may be disposed outside the region where the discharge port 122 is formed. The pilot magnet 125 may have a ring structure. The pilot magnet 125 may be and/or may include a permanent magnet. The pilot magnet 125 may be made of and/or may include a neodymium (Nd) magnet and/or a ferrite magnet. That is, the pilot magnet 125 may create a magnetic field in a surrounding space of the pilot magnet 125.

Returning to FIG. 1 and FIG. 2, an electrode protection member 130 may be disposed at a lower side of the pilot electrode 120. The electrode protection member 130 may have a ring structure. The electrode protection member 130 may be provided in a shape corresponding to the lower end portion of the pilot electrode 120. The electrode protection member 130 may at least partially block the lower end portion of the pilot electrode 120 from being exposed to the space of the discharge port 122.

The electrode protection member 130 may be connected to the lower portion of the electrode supporting member 140. Accordingly, the pilot electrode 120 may be disposed inside the space formed by the electrode supporting member 140 and the electrode protection member 130.

The electrode protection member 130 may be provided as an insulator. That is, the electrode protection member 130 may consist of and/or may include a material having a relatively large corrosion resistance against a gas having corroding properties. Alternatively or additionally, the electrode protection member 130 may consist of and/or may include a material having a relatively high heat resistance. For example, the electrode protection member 130 may be made of and/or may include a ceramic material and/or the like.

The separation gap 121 may be connected to the discharge gas flow path 150. The discharge gas flow path 150 may be connected to the separation gap 121 via the upper portion of the housing 100 and the electrode supporting member 140. The discharge gas flow path 150 may supply a discharge gas that may excite the plasma. The discharge gas may be and/or may include an inert gas such as, but not limited to, nitrogen (N), argon (Ar), and the like. Alternatively or additionally, the discharge gas may include air, hydrogen (H), helium (He), and the like.

A process space PS may be formed below the cathode 111 and the pilot electrode 120. The process space PS may be opened downwards.

The anode 200 may be disposed on the outer region of the pilot electrode 120. The anode 200 may be disposed at the lower side than the pilot electrode 120. The anode 200 may be disposed on the outer circumference of the process space PS. The anode 200 may have a ring structure. Alternatively or additionally, the anode 200 may be provided in a circular arc shape, and two or more may be continuously arranged along the circumference direction of the process space PS, thereby forming a ring. The anode 200 may consist of and/or may include a conductive material. For example, the anode 200 may be made of and/or may include, but not be limited to, copper (Cu) and/or the like.

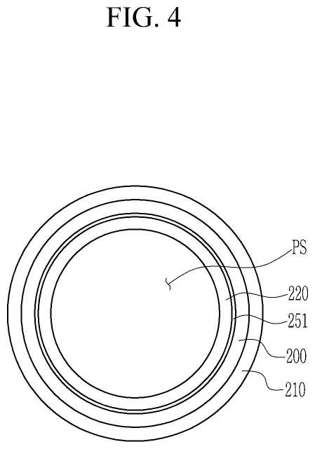

FIG. 4 is a transverse cross-sectional view of a point in the up-down direction on an anode, according to an embodiment.

Referring to FIG. 4, an anode magnet 210 may be disposed on the outer circumference of at least one region of the anode 200. The anode magnet 210 may be disposed on the outer circumference of the upper portion of the anode 200. The anode magnet 210 may have a ring structure. The anode magnet 210 may be and/or may include a permanent magnet. For example, the anode magnet 210 may consist of and/or may include a neodymium (Nd) magnet, a ferrite magnet, and/or the like. That is, the anode magnet 210 may create a magnetic field in the surrounding space around the anode magnet 210.

As shown in FIG. 1 and FIG. 4, blocking members (e.g., an upper blocking member 220 and a lower blocking member 230) may be disposed around the anode 200. The blocking members 220 and 230 may be disposed to surround the process space PS. Alternatively or additionally, the blocking members 220 and 230 may be disposed to at least partially surround the cathode 111 and the outer circumference of the pilot electrode 120. The blocking members 220 and 230 may respectively include the upper blocking member 220 and the lower blocking member 230.

The upper blocking member 220 may be positioned in the upper region of the anode 200. The upper blocking member 220 may consist of and/or may include an insulator. For example, the upper blocking member 220 may be made of and/or may include a material having a high corrosion resistance against a gas having corroding properties. Alternatively or additionally, the upper blocking member 220 may be made of and/or may include a material having a high heat resistance. For example, the upper blocking member 220 may be made of and/or may include a ceramic material and/or the like. The upper blocking member 220 may be disposed to at least partially surround the upper part of the process space PS. Alternatively or additionally, the upper blocking member 220 may be disposed to at least partially surround the cathode 111 and the outer circumference of the pilot electrode 120.

At least some regions between the upper blocking member 220 and the anode 200 may be separated from each other, and an upper protection gas implant gap 222 may be formed therebetween. The upper protection gas implant gap 222 may be connected to the process space PS. For example, the inner end of the upper protection gas implant gap 222 may be formed in a ring shape between the anode 200 and the upper blocking member 220. In addition, the inner end of the upper protection gas implant gap 222 may be positioned between the anode 200 and the upper blocking member 220, and the inner end of the upper protection gas implant gap 222 may be formed of at least one or more hole along the circumference direction of the process space PS with the up-down direction as an axis.

The upper blocking member 220 may be provided to at least partially cover the upper inner surface of the anode 200. The anode magnet 210 may be disposed outside the region at least partially covered by the blocking member in the upper portion of the anode 200. Accordingly, the anode magnet 210 may effectively form a magnetic field in the upper space of the region where the anode 200 may be exposed to the process space PS.

The flow path formation member 221 may be disposed on the inflow path IR. The flow path formation member 221 may be provided as a piping structure and may be disposed in the outer circumference of the pilot electrode 120. The lower portion of the flow path formation member 221 may be connected to the upper blocking member 220. The flow path formation member 221 may consist of and/or may include an insulator. The flow path formation member 221 may be made of and/or may include the same material as the upper blocking member 220, and may extend upward from the upper blocking member 220. The upper portion, inner surface, and exterior surface of the flow path formation member 221 may be provided to be exposed to the inflow path IR. Accordingly, in the inflow path IR, a flow path from the exterior surface of the flow path formation member 221 toward the inner surface of the flow path formation member 221 via the upper portion of the flow path formation member 221 may be formed.

The lower blocking member 230 may be disposed in the lower region of the anode 200. The lower blocking member 230 may consist of and/or may include an insulator. The lower blocking member 230 may be made of and/or may include a material having high corrosion resistance against a gas having corroding properties. Alternatively or additionally, the lower blocking member 230 may be made of and/or may include a material having high heat resistance. For example, the lower blocking member 230 may be made of and/or may include a ceramic material and/or the like. The lower blocking member 230 may be disposed to at least partially surround the lower part of the process space PS.

At least some regions between the lower blocking member 230 and the anode 200 may be separated from each other, and a lower protection gas implant gap 231 may be formed therebetween. The lower protection gas implant gap 231 may be connected to the process space PS. For example, the inner end of the lower protection gas implant gap 231 may be formed in a ring shape between the anode 200 and the lower blocking member 230. In addition, the inner end of the lower protection gas implant gap 231 may be positioned between the anode 200 and the lower blocking member 230, and the inner end of the lower protection gas implant gap 231 may be formed of at least one or more holes with the up-down direction as axis along the circumference direction of the process space PS.

The anode 200 may be connected to the anode supporting member 240. The anode supporting member 240 may be disposed on the outer circumference of the anode 200. The anode supporting member 240 may be connected to the housing 100. The anode supporting member 240 may consist of and/or may include a conductive material. Accordingly, when a voltage is applied to the anode supporting member 240, the same and/or a substantially similar voltage may be applied to the anode 200. The upper blocking member 220 may be connected to the anode supporting member 240. The lower blocking member 230 may be connected to the anode supporting member 240. A cooling flow path through which a cooling water circulates may be formed inside the anode supporting member 240.

The upper protection gas implant gap 222 may be connected to the upper protection gas flow path 251. The upper protection gas flow path 251 may be connected to the upper protection gas implant gap 222 via the anode supporting member 240. The upper protection gas flow path 251 may supply a protection gas for protection of the anode 200. The protection gas supplied by the upper protection gas flow path 251 may be and/or may include an inert gas such as, but not limited to, nitrogen (N), argon (Ar), and/or the like.

The lower protection gas implant gap 231 may be connected to the lower protection gas flow path 252. The lower protection gas flow path 252 may be connected to the lower protection gas implant gap 231 via the anode supporting member 240. The lower protection gas flow path 252 may supply a protection gas for protection of the anode 200. The protection gas supplied by the lower protection gas flow path 252 may be and/or may include an inert gas such as, but not limited to, nitrogen (N), argon (Ar), and/or the like.

The upper reaction gas flow path 310 may be connected to the region adjacent to the discharge port 122. The upper reaction gas flow path 310 may supply a reaction gas having a reactivity with by-products generated after the waste gas is thermally decomposed by plasma. For example, the reaction gas supplied by the upper reaction gas flow path 310 may include, but not be limited to, oxygen (O), hydrogen (H), ammonia (NH₃), and the like. Alternatively or additionally, the reaction gas may be supplied by mixing with an aqueous vapor. The upper reaction gas flow path 310 may be formed via the upper portion of the housing 100 and the electrode supporting member 140. The inner end portion of the upper reaction gas flow path 310 may be provided to face the process space PS. For example, the inner end of the upper reaction gas flow path 310 may be formed in a ring shape disposed at the outer circumference of the pilot electrode 120. In addition, the inner end of the upper reaction gas flow path 310 may be formed of at least one or more holes along the circumference direction of the pilot electrode 120.

The lower reaction gas flow path 320 may be connected to the region positioned below the anode 200. The lower reaction gas flow path 320 may supply a reaction gas having a reactivity with by-products generated after the waste gas is thermally decomposed by plasma. For example, the reaction gas supplied by the lower reaction gas flow path 320 may include, but not be limited to, oxygen (O), hydrogen (H), ammonia (NH₃), and the like. Alternatively or additionally, the reaction gas may be supplied by mixing with an aqueous vapor. The lower reaction gas flow path 320 is provided via the lower blocking member 230, and the inner end of the lower reaction gas flow path 320 may be disposed on the inner surface of the lower blocking member 230. In addition, the lower reaction gas flow path 320 may be disposed to be via the anode supporting member 240.

The inner end of the lower reaction gas flow path 320 may be provided to face the process space PS. For example, the inner end of the lower reaction gas flow path 320 may be formed in a ring shape on the inner surface of the lower blocking member 230 with the up-down direction as an axis. In an embodiment, the inner end of the lower reaction gas flow path 320 may be formed of at least one or more holes along the circumference direction with the up-down direction as an axis on the inner surface of the lower blocking member 230.

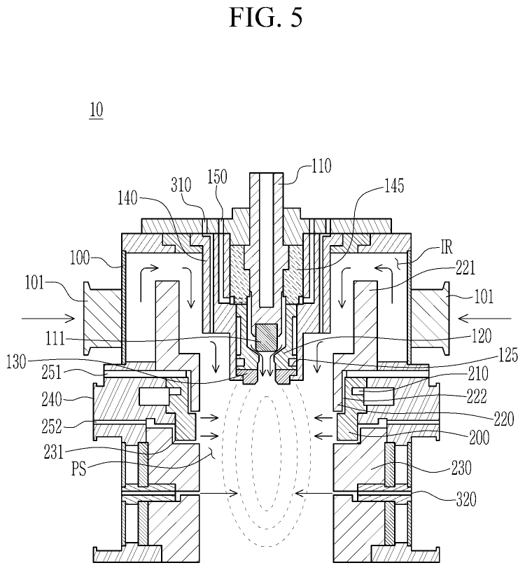

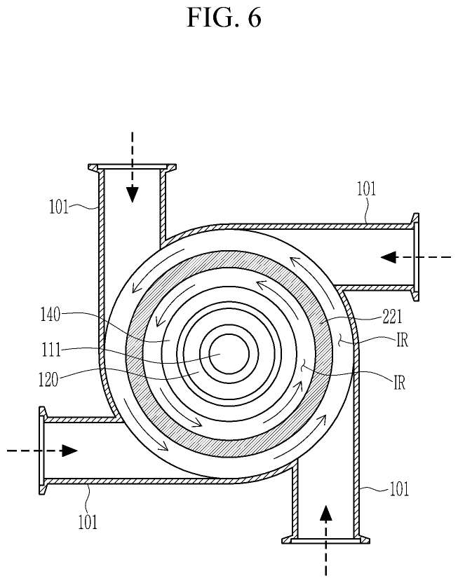

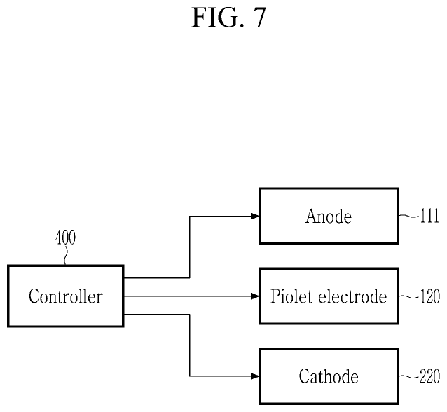

FIG. 5 is a view showing a plasma torch in an operation state, according to an embodiment. FIG. 6 is a transverse cross-sectional view of a region where a waste gas inflow portion and an inflow path are positioned, according to an embodiment. FIG. 7 is a block diagram showing a control relationship of a plasma torch, according to an embodiment.

Referring to FIG. 5 to FIG. 7, the controller 400 may apply voltages to a cathode 111 and a pilot electrode 120 so that a voltage difference may be generated between the cathode 111 and the pilot electrode 120. In an embodiment, the voltages may be applied so that the cathode 111 may have a negative polarity. An insulating breakdown may occur due to the voltage difference between the cathode 111 and the pilot electrode 120, and an arc may be generated between the cathode 111 and the pilot electrode 120.

The discharge gas flow path 150 may supply a discharge gas to the separation gap 121. The discharge gas may be supplied to the process space PS through the discharge port 122. The discharge gas may be excited to the plasma state by the arc.

In an embodiment, the controller 400 may apply a voltage to the anode 200 to generate a voltage difference between the cathode 111 and the anode 200. For example, the voltages may be applied so that the cathode 111 may have a negative polarity. The arc generated between the cathode 111 and the pilot electrode 120 may be transferred to the process space PS by the discharge gas, and an arc may be generated between the cathode 111 and the anode 200. When the arc occurs between the cathode 111 and the anode 200, the controller 400 may block (e.g., prevent) the application of the voltage to the pilot electrode 120.

The arc generated between the cathode 111 and the anode 200 may be rotated in a spiral direction with the up-down direction as an axis by the magnetic field generated by the pilot magnet 125 and the anode magnet 210. Accordingly, the arc may more effectively excite the discharge gas into a plasma state when compared to a related plasma torch. The anode magnet 210 may be disposed above the region exposed to the process space PS in the anode 200, so the arc may be rotated more effectively.

The region where the arc is formed in the cathode 111 may have a relatively narrow area. Alternatively or additionally, the region where the arc is formed at the anode 200 may have a relatively wide area. When the degree of the change of the region connected to one end of the arc at the anode 200 increases, the shape of the arc formed between the cathode 111 and the anode 200 may change greatly over a time. The plasma may be effectively excited when the arc has a uniform shape. Accordingly, in the plasma torch 10, according to an embodiment, the region connected to the arc at the anode 200 may be limited to a region exposed between the upper blocking member 220 and the lower blocking member 230. Accordingly, the degree of the change of the region connected to one end of the arc in the anode 200 may be limited, so that the shape of the arc may be maintained more uniformly and the plasma may be effectively excited, when compared to a related plasma torch.

When one end of the arc is dragged to a region other than the anode 200, the plasma may not be excited at a high density in the region around the anode 200. Consequently, an efficiency of waste gas processing by plasma may be deteriorated (e.g., reduced). Accordingly, in the plasma torch 10, according to an embodiment, on the region surrounding the process space PS, and the inner surface of the upper blocking member 220 and the inner surface of the lower blocking member 230 may be positioned in the regions other than the anode 200. As such, the arc being dragged to the region other than the anode 200 may be prevented from occurring. Consequently, the plasma may be more effectively excited at high density in the region adjacent to the anode 200, when compared to a related plasma torch.

The waste gas may be supplied through the waste gas inflow portion 101. As the waste gas inflow portion 101 is disposed eccentrically in the radial direction with respect to the straight line passing through the central region inside the housing 100, the waste gas supplied to the inside of the housing 100 may be rotated in a spiral shape. That is, the waste gas may be supplied to the process space PS through the outer region of the flow path formation member 221 and the inner region of the flow path formation member 221 in the rotating state. Accordingly, the waste gas may inflow into the process space PS in a uniformly distributed state while rotating, and may be thermally decomposed by the plasma excited to a high temperature in the process space PS.

When waste gas is thermally decomposed, by-products may be generated. The by-products may include, but not be limited to, hydrogen fluoride (HF), hydrogen chloride (HCl), fluorine (F₂), chlorine (Cl₂), and the like. Alternatively or additionally, the excited plasma may have a relatively high temperature (e.g., about 2,000 degrees Centigrade (° C.) or more), and/or the by-products generated from the thermal decomposition of the waste gas may also be in a relatively high temperature state. The generated by-product in the high temperature state may have a relatively large corrosion property.

Alternatively or additionally, in the plasma torch 10, according to an embodiment, the electrode protection member 130 may be disposed at the low side of the pilot electrode 120. Accordingly, the contact of the pilot electrode 120 with the by-product may be blocked, and an etching, or corroding of the pilot electrode 120 by the reaction with the by-product may be prevented.

When the waste gas is thermally decomposed by plasma, the upper protection gas flow path 251 may supply a protection gas. In addition, when the thermal decomposition of the waste gas by plasma is performed, the lower protection gas flow path 252 may supply the protection gas. The protection gas may be supplied to the space around the anode 200, thereby forming a protection layer around the anode 200. The protection layer formed by the protection gas may block the decomposition by-products of the waste gas from being in contact with the anode 200.

When the thermal decomposition of the waste gas by plasma is performed, the upper reaction gas flow path 310 may supply a reaction gas. In addition, when the waste gas is thermally decomposed by plasma, the lower reaction gas flow path 320 may supply reaction gas. The by-products generated from the thermal decomposition of the waste gas may be provided in a high temperature state. Accordingly, a recombination may be generated by reacting the by-products with each other. When the by-products react and recombine, the processing efficiency of the waste gas may decrease. Alternatively or additionally, in the plasma torch 10, according to an embodiment, the by-product may react with the reaction gas and may be removed. Accordingly, the by-products generated by the thermal decomposition of the waste gas may be removed, and the recombination of the by-products may be reduced. In addition, the upper reaction gas flow path 310 and the lower reaction gas flow path 320 may be provided to supply the reaction gas toward the process space PS, thereby supplying the reaction gas to a region where the by-products are generated by the thermal decomposition of the waste gas.

The upper reaction gas flow path 310 may supply the reaction gas above the region where the protection gas supplied by the upper protection gas flow path 251 is supplied, so that the reaction gas may be prevented from contacting the anode 200, and potentially etching and/or corroding the anode 200.

In an embodiment, the lower reaction gas flow path 320 may supply the reaction gas below the region where the protection gas is supplied by the lower protection gas flow path 252, so that the reaction gas may be prevented from contacting the anode 200, and potentially etching and/or corroding the anode 200.

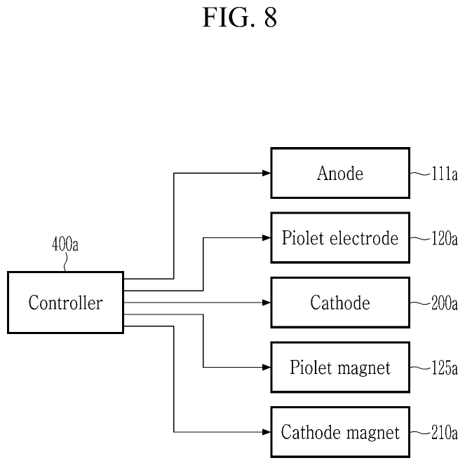

FIG. 8 is a block diagram showing a control relationship of a plasma torch, according to another embodiment.

Referring to FIG. 8, a controller 400a may control voltages applied to a cathode 111a, a pilot electrode 120a, and an anode 200a. Accordingly, a first arc may be generated between the cathode 111a and the pilot electrode 120a, and a second arc may be generated between the cathode 111a and the anode 200a. The method for controlling the voltages applied to the cathode 111a, the pilot electrode 120a, and the anode 200a by the controller 400a may be the same and/or may be similar in many respects to the controlling method described above in FIG. 5 to FIG. 7, and may include additional features not mentioned above. Consequently, repeated descriptions of the controlling method described above with reference to FIG. 5 to FIG. 7 may be omitted for the sake of brevity.

The pilot magnet 125a may be and/or may include an electromagnet. The controller 400a may apply a current to the pilot magnet 125a before applying the voltage to the anode 200a so that the pilot magnet 125a may form a magnetic field. The controller 400a may apply the current to the pilot magnet 125a while applying the voltage to the anode 200a. The controller 400a may apply the current to the pilot magnet 125a after applying the voltage to the anode 200a.

The anode magnet 210a may be and/or may include an electromagnet. The controller 400a may apply the current to the anode magnet 210a before applying the voltage to the anode 200a, so that the anode magnet 210a may form a magnetic field. The controller 400a may apply the current to the anode magnet 210a while applying the voltage to the anode 200a. The controller 400a may apply the current to the anode magnet 210a after applying the voltage to the anode 200a.

The controller 400a may simultaneously and/or at a substantially similar time period may apply a current to the pilot magnet 125a and the anode magnet 210a. Alternatively or additionally, the controller 400a may apply a current to at least one of the pilot magnet 125a and the anode magnet 210a, and then apply the current to the other one of the pilot magnet 125a and the anode magnet 210a.

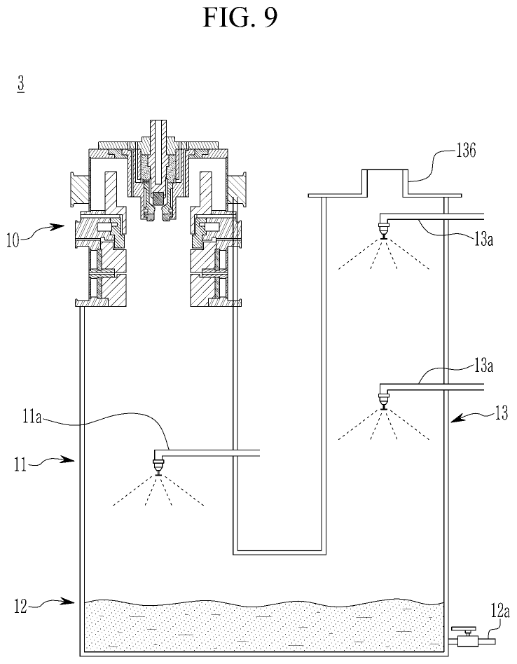

FIG. 9 is a view showing a plasma scrubber apparatus including a plasma torch, according to an embodiment.

Referring to FIG. 9, a plasma scrubber apparatus 3 may include a plasma torch 10, a connection portion 11, a tank portion 12, and a post-processor 13.

As described with reference to FIG. 1 to FIG. 8, the plasma torch 10 may thermally decompose a waste gas through plasma.

The connection portion 11 may be connected to the plasma torch 10. The connection portion 11 may be connected to the lower side of the process space PS. The connection portion 11 may be extended in an up-down direction with a piping structure. The internal space of the connection portion 11 may be connected to the process space PS of the plasma torch 10. By-products, a protection gas, and the like, generated inside the plasma torch 10 may be moved to the connection portion 11. In addition, the thermal decomposition of the waste gas by plasma may be additionally performed in the connection portion 11. A cooling nozzle 11a may be disposed on the connection portion 11. The cooling nozzle 11a may inject a cooling fluid into the inner space of the connection portion 11. The cooling fluid may be and/or include, but not be limited to water and/or the like. The by-products may be cooled by the cooling fluid. In addition, soluble materials in the by-products may be at least partially dissolved in the cooling fluid.

One end portion of the tank portion 12 may be connected to the lower portion of the connection portion 11. The inner space of the tank portion 12 may extend in a direction crossing the length direction of the connection portion 11. The tank portion 12 may be provided to store a fluid. The fluid may be and/or may include, but not be limited to, water and/or the like. When the by-products inflowed from the connection portion 11 move to the inner space of the tank portion 12, soluble materials included in the by-products may be at least partially dissolved in the fluid stored in the tank portion 12. A vent portion 12a may be disposed on one side of the tank portion 12. The vent portion 12a may discharge the fluid stored in the tank portion 12 to the outside.

The post-processor 13 may be connected to the other end portion of the tank portion 12. The post-processor 13 may extend in an upward direction from the tank portion 12 with a piping structure. An outlet 13b may be disposed in the upper portion of the post-processor 13. The outlet 13b may discharge a gas remained by processing the waste gas from the plasma scrubber apparatus 3. A post processing nozzle 13a for a post processing may be disposed inside the post-processor 13. The post processing nozzle 13a may inject a post processing fluid. The post processing fluid may be and/or may include, but not be limited to, water and/or the like. The post processing fluid may additionally remove a soluble material from the discharged gas.

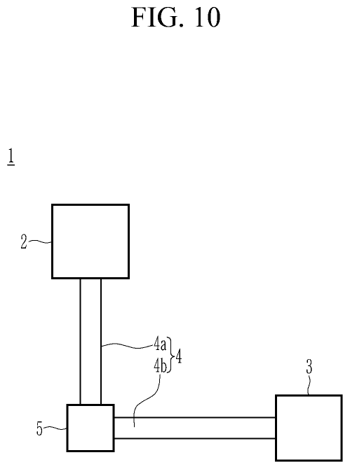

FIG. 10 is a view showing a semiconductor production equipment including a plasma scrubber apparatus of FIG. 9, according to an embodiment.

Referring to FIG. 10, a semiconductor production equipment 1 may include a substrate processing apparatus 2 and a plasma scrubber apparatus 3.

The substrate processing apparatus 2 may perform a processing process for a substrate. The processing process performed by the substrate processing apparatus 2 may include, but not be limited to, an etching process, a deposit process, a diffusion process, an ashing process, and the like. A waste gas may be generated during the processing of the substrate by the substrate processing apparatus 2.

The plasma scrubber apparatus 3 may be connected to the substrate processing apparatus 2 through the discharge piping 4. The waste gas generated in the substrate processing apparatus 2 may move to the plasma scrubber apparatus 3 through the discharge piping 4. A pump 5 may be disposed in one section of the discharge piping 4. The discharge piping 4 may include a front pipe part 4a disposed between the pump 5 and the substrate processing apparatus 2, and a rear pipe part 4b disposed between the pump 5 and the plasma scrubber apparatus 3.

While the present disclosure has been described in connection with what is presently considered to be practical embodiments, it is to be understood that the present disclosure is not limited to the disclosed embodiments. However, the present disclosure is intended to cover various modifications and equivalent arrangements included within the spirit and scope of the appended claims.

What is claimed is:

1. A plasma torch, comprising:
a cathode;
a pilot electrode disposed on a first outer circumference of the cathode and separated from an exterior surface of the cathode;
an electrode protection member disposed below the pilot electrode and comprising a first insulator;
an anode disposed on a second outer circumference of a process space and disposed below the pilot electrode; and
a discharge gas flow path coupled to a separation gap formed between the exterior surface of the cathode and an inner surface of the pilot electrode, the discharge gas flow path being configured to supply a discharge gas.

2. The plasma torch of claim 1, further comprising an upper blocking member disposed on an upper area of the anode and provided as a second insulator.

3. The plasma torch of claim 2, wherein a first region and a second region disposed between the upper blocking member and the anode are separated from each other, and
wherein the first region and the second region form an upper protection gas implant gap.

4. The plasma torch of claim 3, further comprising an upper protection gas flow path coupled to the upper protection gas implant gap and configured to supply a protection gas forming a protection layer of the anode.

5. The plasma torch of claim 2, further comprising a flow path formation member provided as a piping structure, disposed on a third outer circumference of the pilot electrode, and having a lower portion coupled to the upper blocking member.

6. The plasma torch of claim 5, wherein the flow path formation member comprises a third insulator.

7. The plasma torch of claim 6, wherein the flow path formation member comprises a same material as the upper blocking member, and
wherein the flow path formation member extends upward from the upper blocking member.

8. The plasma torch of claim 1, further comprising a lower blocking member disposed on a lower area of the anode and comprising a fourth insulator.

9. The plasma torch of claim 8, wherein a first region and a second region disposed between the lower blocking member and the anode are separated from each other, and
wherein the first region and the second region form a lower protection gas implant gap.

10. The plasma torch of claim 9, further comprising a lower protection gas flow path coupled to the lower protection gas implant gap and configured to supply a protection gas forming a protection layer of the anode.

11. The plasma torch of claim 1, further comprising:
an upper reaction gas flow path configured to supply a reaction gas to an area adjacent to a discharge port,
wherein the discharge port is formed inside a lower end portion of the pilot electrode, and
wherein the reaction gas has a reactivity with by-products generated after a waste gas is thermally decomposed by plasma.

12. The plasma torch of claim 11, further comprising:
an electrode supporting member disposed on a third outer circumference of the pilot electrode, and
wherein the upper reaction gas flow path is formed via the electrode supporting member.

13. The plasma torch of claim 1, further comprising:
a lower reaction gas flow path configured to supply a reaction gas to an area positioned below the anode, and
wherein the reaction gas has a reactivity with by-products generated after a waste gas is thermally decomposed by plasma.

14. The plasma torch of claim 13, further comprising:
a lower blocking member disposed on a lower area of the anode and comprises a fifth insulator, and
wherein the lower reaction gas flow path is formed via the lower blocking member.

15. A plasma torch, comprising:
a cathode;
a pilot electrode disposed on a first outer circumference of the cathode and separated from an exterior surface of the cathode;
an anode disposed on a second outer circumference of a process space and disposed below the pilot electrode;
a discharge gas flow path coupled to a separation gap formed between the exterior surface of the cathode and an inner surface of the pilot electrode, the discharge gas flow path being configured to supply a discharge gas;
an electrode protection member disposed below the pilot electrode and comprises a first insulator;
an upper blocking member comprising a second insulator, disposed on an upper area of the anode, and at least partially surrounding the process space; and
a lower blocking member comprising a third insulator, disposed on a lower area of the anode, and at least partially surrounding the process space.

16. The plasma torch of claim 15, further comprising a pilot magnet disposed on a third outer circumference of the pilot electrode.

17. The plasma torch of claim 16, wherein the pilot magnet is an electromagnet.

18. The plasma torch of claim 15, further comprising an anode magnet disposed on a third outer circumference of the anode.

19. The plasma torch of claim 18, wherein the anode magnet is an electromagnet.

20. A plasma torch, comprising:
a cathode;
a pilot electrode disposed on a first outer circumference of the cathode and separated from an exterior surface of the cathode;
an electrode protection member disposed below the pilot electrode and comprising a first insulator;
an anode disposed on a second outer circumference of a process space and disposed below the pilot electrode;
a discharge gas flow path coupled to a separation gap formed between the exterior surface of the cathode and an inner surface of the pilot electrode, the discharge gas flow path being configured to supply a discharge gas;
an upper reaction gas flow path configured to supply a reaction gas to an area adjacent to a discharge port; and
a lower reaction gas flow path configured to supply the reaction gas to an area positioned below the anode,
wherein the discharge port is formed inside a lower end portion of the pilot electrode, and
wherein the reaction gas has a reactivity with by-products generated after a waste gas is thermally decomposed by plasma.
